(19) United States
(12) Patent Application Publication
(10) Pub. No.: US 2026/0100684 A1
(43) Pub. Date: Apr. 9, 2026

(54) LOW-POWER OPERATIONAL AMPLIFIER

(71) Applicant: STMicroelectronics International N.V., Geneva (CH)

(72) Inventors: Francesco Borgioli, Livorno (IT); Angelo Recchia, Fasano (IT)

(21) Appl. No.: 18/907,837

(22) Filed: Oct. 7, 2024

(51) Int. Cl. H03F 3/45; H03F 3/21

(52) U.S. Cl. CPC H03F 3/45076; H03F 3/21; H03F 2200/129

(57) ABSTRACT

According to an embodiment, an analog front-end (AFE) circuit includes a power amplifier and a trans-impedance amplifier. At least one of the amplifiers comprises a differential pair of transistors receiving input signals, a folded cascode structure coupled to the differential pair of transistors, and a nulling transistor coupled to the differential pair of transistors. The nulling transistor receives a nulling signal. A tail current of the differential pair of transistors, bias currents in the folded cascode structure, and a nulling current through the nulling transistor are selected such that a sum of half the tail current and a first bias current equals a sum of a second bias current and the nulling current. The configuration reduces flicker noise and offset of the amplifier without significantly increasing current consumption, enabling improved performance in low-power applications such as portable medical devices.

### TECHNICAL FIELD

The present disclosure generally relates to electronic devices and, in particular embodiments, to a low-power operational amplifier.

### BACKGROUND

Electrochemical cells are used in various applications, including continuous glucose monitoring systems in medical devices. These cells generate electrical signals corresponding to the concentration of specific analytes in a sample through chemical reactions. Specialized electronic circuits known as analog front-ends (AFEs) are employed to interface with these cells and process their signals.

Operational amplifiers are a component of AFE circuits used for electrochemical cells. These amplifiers perform multiple functions, such as biasing the electrodes of the electrochemical cell and sensing the currents generated by the electrochemical reactions. These amplifiers' performance can affect the sensing system's accuracy and reliability.

Certain performance parameters of operational amplifiers are of interest in electrochemical cell applications. High input impedance helps ensure that the amplifier does not significantly influence the cell by drawing current. Low offset voltage aids in accurately sensing the small signals generated by the electrochemical reactions, particularly when measuring low concentrations of analytes.

Designing AFE circuits for electrochemical cells involves addressing specific considerations. The currents generated by electrochemical cells are often very small, sometimes in the range of nanoamperes or picoamperes. This typically necessitates amplifiers with high sensitivity and low noise characteristics. Additionally, the dynamic range of these signals can be quite large, requiring amplifiers that can handle very small and relatively large signals.

Recent developments in medical devices have led to increased interest in portable and implantable systems that use electrochemical sensing. These devices, such as wearable glucose monitors, have specific requirements for the power consumption of their electronic components. AFE circuits in these devices are designed to operate on minimal power to extend battery life and improve overall device usability.

### SUMMARY

Technical advantages are generally achieved by embodiments of this disclosure, which describe a low-power operational amplifier.

A first aspect relates to an analog front-end (AFE) circuit. The AFE circuit comprising a power amplifier; and a trans-impedance amplifier, wherein at least one of the power amplifier or trans-impedance amplifier comprises a differential pair of transistors receiving input signals, a folded cascode structure coupled to the differential pair of transistors, and a nulling transistor coupled to the differential pair of transistors, the nulling transistor receiving a nulling signal, and wherein a tail current of the differential pair of transistors, bias currents in the folded cascode structure, and a nulling current through the nulling transistor are selected such that a sum of half the tail current and a first bias current equals a sum of a second bias current and the nulling current, thereby reducing flicker noise and offset of the power amplifier or the trans-impedance amplifier.

A second aspect relates to an operational amplifier comprising a main differential pair of n-channel transistors receiving input signals; a folded cascode structure coupled to the differential pair of transistors; and a pair of p-channel nulling transistors, each having a source terminal coupled to a supply voltage and a drain terminal coupled to a drain terminal of a respective transistor of the differential pair of transistors, wherein the pair of p-channel nulling transistors receive nulling signals, and wherein a tail current of the differential pair of transistors, bias currents in the folded cascode structure, and nulling currents through the pair of p-channel nulling transistors are selected such that a sum of half the tail current and a first bias current equals a sum of a second bias current and the nulling currents, thereby reducing flicker noise and offset of the operational amplifier.

A third aspect relates to a nulling circuit. The nulling circuit comprising a main amplifier including a differential pair of transistors receiving input signals, a folded cascode structure coupled to the differential pair of transistors, and at least one nulling transistor coupled to the differential pair of transistors; a nulling amplifier providing a nulling signal to the at least one nulling transistor; and a resistor divider coupled between an output of the main amplifier and an input of the nulling amplifier, wherein a tail current of the differential pair of transistors, bias currents in the folded cascode structure, and a nulling current through the at least one nulling transistor are selected such that a sum of half the tail current and a first bias current equals a sum of a second bias current and the nulling current, thereby reducing flicker noise and offset of the main amplifier.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a system block diagram of a system comprising an electrochemical cell coupled to an analog front-end (AFE) circuit;

FIG. 2 is a schematic of an embodiment nulling circuit in a fully differential topology;

FIG. 3 is a schematic of an embodiment nulling port circuit;

FIG. 4 is a schematic of an embodiment nulling circuit in a single-ended topology; and

FIG. 5 is a schematic of an embodiment nulling port circuit for a single-ended topology.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of analog front-end circuits for electrochemical cells used in continuous glucose monitoring systems, it should also be appreciated that these inventive aspects may also apply to other types of sensor systems and analog circuits. In particular, aspects of this disclosure may similarly apply to various biomedical sensing applications, environmental monitoring systems, and other precision analog circuits where low offset, high input impedance, and low power consumption are desirable characteristics.

Aspects of the disclosure relate to an operational amplifier with a nulling port for low power consumption. The operational amplifier includes a main amplifier and a nulling amplifier. The main amplifier can be implemented as a folded cascode structure with additional input transistors as the nulling port. The additional input transistors are connected to the output of the nulling amplifier.

In embodiments of the disclosure, the nulling port is integrated into the operational amplifier's first stage. This first stage's topology may be a folded cascode structure. The configuration allows for the addition of the nulling port without significantly increasing the amplifier's overall current consumption.

The configuration can be implemented in fully differential and single-ended topologies. In the fully differential topology, the nulling amplifier may have two outputs connected to two additional input transistors in the main amplifier. For the single-ended topology, the nulling amplifier may have a single output connected to one additional input transistor in the main amplifier.

An aspect of the disclosure involves selecting current values in the circuit. The current flowing through the main differential pair and the current in the cascode branch can be chosen based on the amplifier's desired performance characteristics without considering the nulling port. The current for the nulling port may then be accommodated by adjusting the current in another branch so that the total current consumption remains unchanged.

Embodiments of the disclosure may provide offset cancellation and reduce flicker noise without increasing the amplifier's overall current consumption. The approach can be particularly beneficial in applications where low power consumption is important, such as portable or implantable medical devices.

The operational amplifier with the integrated nulling port can be used in various analog front-end circuits, including those for electrochemical cells. It may be particularly suitable for continuous glucose monitoring systems applications, where high input impedance, low offset, and low power consumption are desirable characteristics. These and other details are further described below.

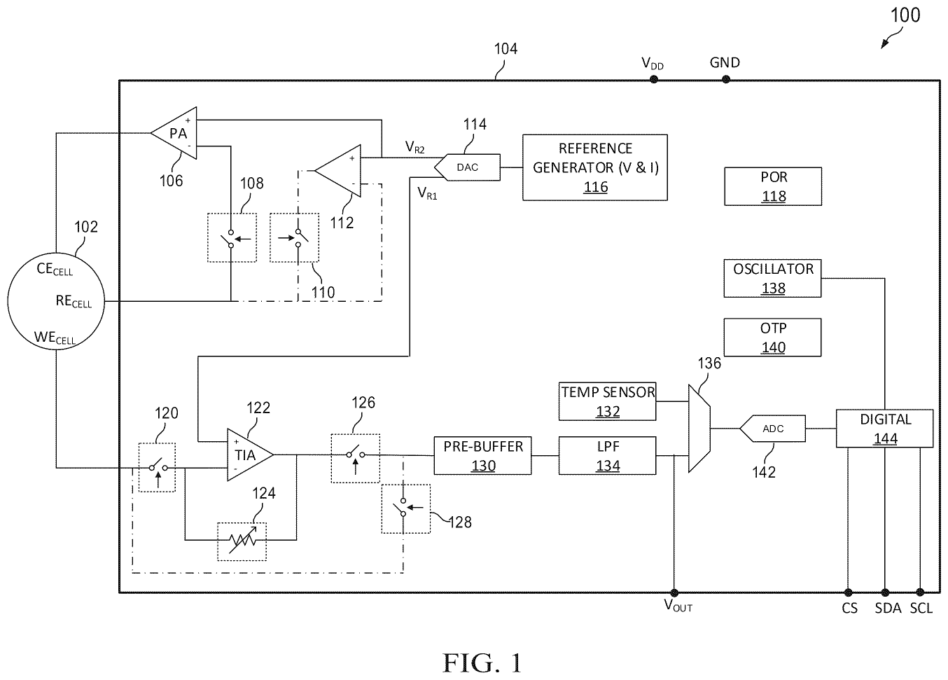

FIG. 1 illustrates a system block diagram of a system 100 comprising an electrochemical cell 102 coupled to an analog front-end (AFE) circuit 104. The system 100 is designed to interface with and process signals from the electrochemical cell 102, providing precise control and measurement capabilities for applications such as continuous glucose monitoring.

The electrochemical cell 102 is configured to facilitate and measure specific chemical reactions for analytical purposes. It includes a counter electrode (CE_{CELL}), a reference electrode (RE_{CELL}), and a working electrode (WE_{CELL}). Each electrode plays a role in the operation and accuracy of the measurements obtained. Together, these three electrodes enable precise control and measurement of the electrochemical reactions occurring within the electrochemical cell 102, allowing for quantitative analysis of the target substances in the sample.

The working electrode (WE_{CELL}) is where the primary electrochemical reaction of interest occurs. In applications such as glucose monitoring, the working electrode (WE_{CELL}) is typically coated with enzymes or other reactive substances that interact specifically with the target analyte. The reference electrode (RE_{CELL}) provides a stable and known electrical potential against which the potential of the working electrode (WE_{CELL}) is measured. The stable reference point allows for accurate and reproducible measurements.

The AFE circuit 104 is configured to read a current coming from the electrochemical cell 102 while precisely controlling the voltages of its electrodes. The power amplifier (PA) 106 and the trans-impedance amplifier (TIA) 122 bias the working electrode (WE_{CELL}) and the reference electrode (RE_{CELL}) to specific voltages, utilizing the virtual short circuit principle. This approach provides high impedance, ensuring minimal current is added to or subtracted from the electrochemical cell 102.

The counter electrode (CE_{CELL}) often has a larger surface area than the working electrode (WE_{CELL}) to ensure that the reactions at the working electrode (WE_{CELL}) are not limited by the performance of the counter electrode (CE_{CELL}).

The AFE circuit 104 includes a power amplifier (PA) 106, a first switch 108, a second switch 110, an operational amplifier 112, a digital-to-analog converter (DAC) 114, a reference generator 116, a power-on-reset (POR) 118, a third switch 120, a trans-impedance amplifier (TIA) 122, a variable resistor 124, a fourth switch 126, a fifth switch 128, a pre-buffer 130, a temperature sensor 132, a low-pass filter (LPF) 134, a multiplexer 136, an oscillator 138, a one-time-programmable (OTP) memory 140, an analog-to-digital converter (ADC) 142, and a digital circuit 144, which may (or may not) be arranged as shown. AFE circuit 104 may include additional components not shown.

The reference generator 116, digital-to-analog converter (DAC) 114, operational amplifier 112, and power amplifier (PA) 106 work to precisely control and operate the electrochemical cell 102. The arrangement forms a control system that maintains accurate voltages and currents for reliable electrochemical measurements.

The process begins with the reference generator 116, which produces stable voltage and current references. The references provide a consistent baseline for all other voltage-related operations in the AFE circuit 104. The reference generator outputs a first voltage (V_{R1}) and a second voltage (V_{R2}), which serve as the primary reference points for the operation of the electrochemical cell 102.

The digital-to-analog converter (DAC) 114 converts digital reference voltages into analog signals fed to the various amplifiers of the AFE circuit 104. The output of the digital-to-analog converter (DAC) 114 feeds into the operational amplifier 112 and the power amplifier (PA) 106, providing them with the target voltage levels.

The operational amplifier 112 is an intermediary between the digital-to-analog converter (DAC) 114 and the power amplifier (PA) 106. It serves multiple functions in this setup. First, it buffers the output of the digital-to-analog converter (DAC) 114, preventing loading effects that could distort the reference voltage. Second, it can amplify small differences between the set point voltage from the digital-to-analog converter (DAC) 114 and the actual voltage at the reference electrode (RE_{CELL}) through the second switch 110, effectively acting as an error amplifier. The error amplification enhances the system's ability to maintain the desired voltage with high precision.

The power amplifier (PA) 106 is configured in a non-inverting arrangement to bias the reference electrode (RE_{CELL}). Its output is coupled to the counter electrode (CE_{CELL}) to close the loop, as the electrochemical cell 102 behaves like two resistors in series.

The arrangement creates a dual feedback loop. The inner loop, formed by the power amplifier (PA) 106 and the electrochemical cell 102, responds quickly to changes in the electrochemical cell 102. The outer loop, which includes the operational amplifier 112, provides additional precision and stability. Together, these loops ensure that the voltage at the reference electrode (RE_{CELL}) is maintained at the desired level set by the digital-to-analog converter (DAC) 114, despite variations in the behavior or external disturbances to the electrochemical cell 102.

By carefully controlling the potential difference between the counter electrode (CE_{CELL}) and the reference electrode (RE_{CELL}), AFE circuit 104 creates the optimal conditions for the electrochemical reactions to occur at the working electrode (WE_{CELL}).

The trans-impedance amplifier (TIA) 122 serves two purposes. First, it biases the working electrode (WE_{CELL}) using a virtual short circuit. Second, it senses the current coming from the working electrode (WE_{CELL}). The dual functionality allows for precise control of the potential at the working electrode (WE_{CELL}) while accurately measuring the resulting current. The arrangement ensures that the tiny currents generated by the electrochemical cell 102 are accurately measured and converted into useful digital data, while maintaining precise control over the cell's electrode potentials. The gain of the trans-impedance amplifier (TIA) 122 can be adjusted using the variable resistor 124, allowing the AFE circuit 104 to accommodate a wide range of input current levels.

From the trans-impedance amplifier (TIA) 122, the signal passes through the pre-buffer 130. This stage provides impedance matching and may offer additional gain or level shifting as needed. It ensures the signal is properly conditioned before the subsequent filtering stage.

The fourth switch 126 and fifth switch 128 provide flexibility in routing signals, enabling different measurement configurations or facilitating self-test and calibration modes. For example, they allow for the injection of known test signals into the trans-impedance amplifier (TIA) 122 or bypass certain stages of the signal processing chain for diagnostic purposes. These additional switches enhance the versatility of the AFE circuit 104, allowing it to adapt to various measurement scenarios or perform internal checks to ensure system integrity and accuracy.

The low-pass filter (LPF) 134 follows the pre-buffer 130. Its primary function is to remove high-frequency noise from the signal, improving the signal-to-noise ratio. This filtering extracts the relevant information from the electrochemical reactions while minimizing interference from external sources or circuit noise.

In parallel to the main signal path, the temperature sensor 132 monitors the ambient or system temperature. Temperature data can be used to compensate for any temperature-dependent variations in the behavior of the electrochemical cell 102 or the AFE circuit 104.

The multiplexer 136 allows the AFE circuit 104 to select between the processed signal from the low-pass filter (LPF) 134 and the temperature sensor data. The flexibility enables the analog-to-digital converter (ADC) 142 to digitize the main signal and temperature information as needed, potentially alternating between them.

The one-time programmable (OTP) memory 140 stores calibration data, system parameters, or other configuration information for correctly interpreting the signals. This could include factors like temperature compensation coefficients or sensor-specific calibration values.

Oscillator 138 provides the clock signals for the system's digital components, ensuring the synchronized operation of the analog-to-digital converter (ADC) 142 and digital circuit 144.

The digital circuit 144 orchestrates the entire process. It controls the multiplexer selection, manages the analog-to-digital converter (ADC) 142 operation, and processes the digitized data. The digital circuit 144 may apply calibration factors stored in the one-time programmable (OTP) memory 140, perform temperature compensation, and execute more complex signal processing algorithms. It can also handle communication with external systems through the serial data (SDA), serial clock (SCL), and chip select (CS) interfaces, allowing the processed data to be transmitted for further analysis or display.

The signal processing chain transforms the tiny electrochemical signals from the electrochemical cell 102 into accurate, stable, and meaningful digital data, enabling precise measurements in applications like continuous glucose monitoring. The combination of analog signal conditioning, precise timing, calibration, and digital processing allows for highly accurate and reliable results from the electrochemical cell measurements.

In embodiments, the analog front-end (AFE) circuit 104 is compatible with a broader ecosystem of sensors and processing units. The integration capability allows for creating more comprehensive and versatile sensing systems. For example, the electrochemical cell interface provided by system 100 can be combined with various MEMS (Micro-Electro-Mechanical Systems) sensors such as accelerometers, gyroscopes, and temperature sensors and coupled to the AFE circuit 104.

The multi-modal approach can synchronize electrochemical measurements with other physical parameters. Such integration can provide a more holistic view of the monitored environment or subject. The digital circuit 144 can be expanded or interfaced with other processing units, including those capable of artificial intelligence and machine learning algorithms. The combination of diverse sensor inputs and processing allows applications that correlate biochemical data with physical activity or environmental conditions.

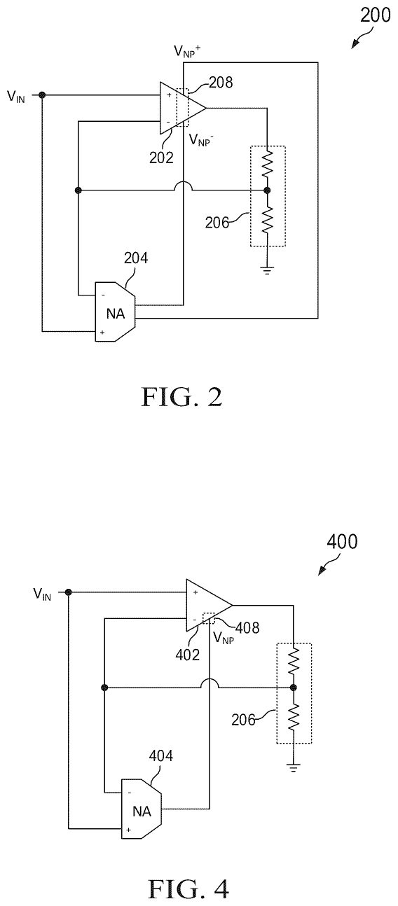

FIG. 2 illustrates a schematic of an embodiment nulling circuit 200 in a fully differential topology. Nulling circuit 200 includes a nulling amplifier 204, a main amplifier 202, and a resistor divider 206, which may (or may not) be arranged as shown. Nulling circuit 200 may include additional components not shown, such as capacitors, filters, or the like. The main amplifier 202 may be implemented as the power amplifier (PA) 106, the trans-impedance amplifier (TIA) 122, or both. The nulling amplifier 204 can be any differential amplifier.

Amplifiers used in analog front-end (AFE) circuits for electrochemical cells, such as those in continuous glucose monitoring systems, can suffer from offset voltage and flicker noise issues. These non-idealities can impact the accuracy and reliability of the sensing system. Offset voltage refers to the small DC voltage that appears at the output of an amplifier when both inputs are at the same potential. The offset can lead to measurement errors, especially when dealing with small input signals. Flicker (1/f) noise is a type of electronic noise that is more pronounced at low frequencies. In precision analog circuits like those found in AFE circuits, flicker noise can mask small signal variations and degrade the overall signal-to-noise ratio.

A conventional technique to address these issues in the power amplifier (PA) 106 or the trans-impedance amplifier (TIA) 122 is using a nulling port 208 in the main amplifier 202 with an auxiliary amplifier (i.e., the nulling amplifier 204). The nulling amplifier 204 senses the offset of the main amplifier 202. It injects a corrective signal through the nulling port 208, reducing the overall offset by dividing it by the gain of the nulling amplifier 204. The technique can also help mitigate flicker noise by continuously adjusting for low-frequency variations.

The midpoint of the resistor divider 206 is coupled to the inverting inputs of the main amplifier 202 and the nulling amplifier 204. This configuration allows both amplifiers to sense the same feedback signal, a scaled version of the output voltage. The resistor divider 206 forms a feedback path from the output of the main amplifier 202, setting the closed-loop gain and ensuring stable operation.

By coupling the inverting inputs of both amplifiers to the same point, the nulling circuit 200 enables the nulling amplifier 204 to accurately sense any offset present in the main amplifier 202. The nulling amplifier 204 can then generate a corrective signal injected through the nulling port 208 to cancel the offset. The ratio of the resistors in the resistor divider 206 determines the gain of the main amplifier 202 and affects the scaling of the sensed offset.

The nulling signals (V_{NP}_{^{−}} and V_{NP}_{⁺}) create small current imbalances in the nulling port 208 that counteract the offset in the main amplifier 202. The magnitude and polarity of the nulling signals (V_{NP}_{^{−}} and V_{NP}_{⁺}) are continuously adjusted based on the detected offset. If the main amplifier's output shows a positive offset, the nulling amplifier 204 will adjust the nulling signals (V_{NP}_{^{−}} and V_{NP}_{⁺}) to effectively “pull” the output in the opposite direction of the offset.

The feedback loop formed by the main amplifier 202, nulling amplifier 204, and nulling port 208 operates continuously, allowing real-time offset correction. The dynamic adjustment helps compensate for initial offset and offset variations due to temperature changes or aging effects.

Regarding flicker noise reduction, the nulling circuit 200 helps by continuously adjusting for low-frequency variations in the operating point of the main amplifier 202. Flicker noise manifests as slow fluctuations in the amplifier's offset. By constantly monitoring and correcting the low-frequency changes, the nulling circuit 200 effectively suppresses a significant portion of the flicker noise, improving the low-frequency noise performance of the main amplifier 202.

The arrangement allows for effective offset cancellation and flicker noise reduction while maintaining a conventional feedback structure for the main amplifier 202. The shared feedback point ensures that the nulling mechanism is tightly integrated with the main amplifier's operation, potentially improving the accuracy of offset cancellation. Additionally, the resistor divider 206, in combination with parasitic capacitances or intentionally added capacitors (not shown), can form a low-pass filter, helping to reduce high-frequency noise in the output of the main amplifier 202.

Existing implementations of nulling port architectures often come with significant drawbacks. For example, one solution involves adding a differential pair with a separate tail current to serve as the nulling port 208. While effective in reducing offset and flicker noise, the approach typically increases the overall current consumption of the main amplifier 202. In applications requiring a high current on the nulling port 208, the additional current consumption can be substantial, potentially doubling the power requirements of the main amplifier 202. The increased power consumption can be particularly problematic in low-power applications such as portable or implantable medical devices, where battery life is critical.

Another limitation of some existing nulling port implementations is their impact on the performance characteristics of the main amplifier 202. For example, certain designs may limit the amplification through the main differential pair and the nulling port 208 due to the lack of a cascaded output resistance. This can constrain the overall gain and bandwidth of the main amplifier 202, potentially compromising its performance in high-speed or high-precision applications.

Further, adding nulling circuitry often increases the complexity and area usage of the amplifier design. In integrated circuit implementations, where silicon area is at a premium, the extra transistors and bias circuitry required for conventional nulling ports can lead to larger chip sizes and potentially higher manufacturing costs.

These drawbacks highlight the need for innovative nulling port architectures to reduce offset voltage and flicker noise without significantly increasing current consumption, compromising amplifier performance, or substantially increasing circuit complexity and area usage.

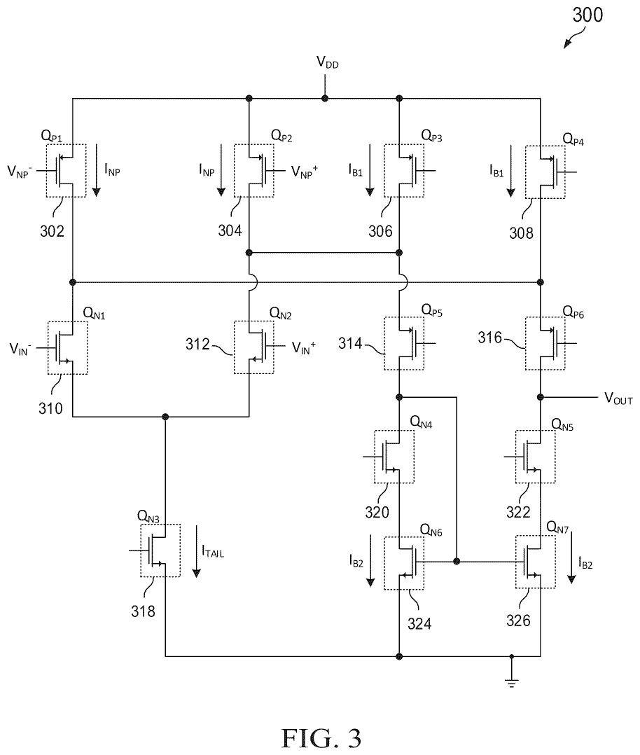

FIG. 3 illustrates a schematic of an embodiment nulling port circuit 300, which may be implemented as the nulling port 208. The nulling port circuit 300 represents the first stage of an operational amplifier with an integrated nulling function.

Nulling port circuit 300 includes a first p-channel transistor (Q_{P1}) 302, a second p-channel transistor (Q_{P2}) 304, a third p-channel transistor (Q_{P3}) 306, a fourth p-channel transistor (Q_{P4}) 308, a fifth p-channel transistor (Q_{P5}) 314, a sixth n-channel transistor (QP6) 316, a first n-channel transistor (Q_{N1}) 310, a second n-channel transistor (Q_{N2}) 312, a third n-channel transistor (Q_{N3}) 318, a fourth n-channel transistor (Q_{N4}) 320, a fifth n-channel transistor (Q_{N5}) 322, a sixth n-channel transistor (Q_{N6}) 324, and a seventh n-channel transistor (Q_{N7}) 326, which may (or may not) be arranged as shown. Nulling port circuit 300 may include additional components not shown.

In embodiments, the third p-channel transistor (Q_{P3}) 306, the fourth p-channel transistor (Q_{P4}) 308, and the third n-channel transistor (Q_{N3}) 318 may be implemented as individual current generators.

The nulling port circuit 300 operates by integrating the nulling function directly into the input stage of the main amplifier 202. The first n-channel transistor (Q_{N1}) 310 and the second n-channel transistor (Q_{N2}) 312 form a main differential pair of transistors, receiving the input signals V_{IN}_{^{−}} and V_{IN}_{⁺}, respectively. The third n-channel transistor (Q_{N3}) 318 acts as a current source, providing the tail current (I_{TAIL}) for the differential pair of transistors.

The gate terminals of the first p-channel transistor (Q_{P1}) 302 and the second p-channel transistor (Q_{P2}) 304 receive the nulling signals (V_{NP}_{^{−}} and V_{NP}_{⁺}), which are provided from the nulling amplifier 204 in the fully differential topology. The drain terminals of these transistors are coupled to the drain terminals of the transistors of the main differential pair of transistors, allowing the nulling signals to influence the amplifier's operation directly. The nulling currents (I_{NP}) through the first p-channel transistor (Q_{P1}) 302 and the second p-channel transistor (Q_{P2}) 304, can be adjusted to control the strength of the nulling effect.

For the fully differential topology shown in FIG. 3, the common mode of the nulling amplifier inputs (V_{NP}_{^{−}} and V_{NP}_{⁺}) is controlled to maintain a specific gate-to-source voltage (V_{GS}) of the first p-channel transistor (Q_{P1}) 302 and the second p-channel transistor (Q_{P2}) 304. These transistors have their source terminals connected to the source voltage (V_{DD}), and the nulling currents (I_{NP}) flow through them. The control of the common mode voltage allows for proper operation of the nulling function and ensures that the first p-channel transistor (Q_{P1}) 302 and the second p-channel transistor (Q_{P2}) 304 remain in the correct operating region.

The nulling currents (I_{NP}) are summed with the signal currents from the main differential pair at the folding nodes. The summation allows the nulling currents (I_{NP}) to directly influence the overall current balance in the nulling port circuit 300, thereby correcting the offset.

The folded cascode configuration is implemented using several transistors. The third p-channel transistor (Q_{P3}) 306 and the fourth p-channel transistor (Q_{P4}) 308 serve as current sources, providing bias currents (I_{B1}) to the upper branches of the folded cascode structure. The fifth p-channel transistor (Q_{P5}) 314 and the sixth n-channel transistor (Q_{P6}) 316 form part of the cascode arrangement, improving the output impedance and voltage gain of the nulling port circuit 300. On the lower side of the nulling port circuit 300, the fourth n-channel transistor (Q_{N4}) 320 and the fifth n-channel transistor (Q_{N5}) 322 complete the folded cascode structure.

The sixth n-channel transistor (Q_{N6}) 324 and the seventh n-channel transistor (Q_{N7}) 326 act as additional current sources, supplying bias currents (I_{B2}) to the lower branches of the cascode. The bias currents (I_{B2}) are chosen based on the design requirements of the first stage of the operational amplifier. This current, along with the tail current (I_{TAIL}) and bias currents (I_{B1}), form part of the current balance in the nulling port circuit 300.

“Folded cascade” describes the specific arrangement of these transistors. The “folded” aspect refers to redirecting the signal path from the n-channel input pair to the p-channel devices (i.e., the third p-channel transistor (Q_{P3}) 306 and the fourth p-channel transistor (Q_{P4}) 308). The “cascade” part relates to stacking transistors (i.e., the fifth p-channel transistor (Q_{P5}) 314, the sixth n-channel transistor (Q_{P6}) 316, the fourth n-channel transistor (Q_{N4}) 320, and the fifth n-channel transistor (Q_{N5}) 322) to enhance performance characteristics such as output impedance and voltage gain.

By integrating the nulling inputs (V_{NP}_{⁺} and V_{NP}_{^{−}}) directly into the input stage alongside the main inputs (V_{IN}_{⁺} and V_{IN}_{^{−}}), the nulling port circuit 300 can perform offset cancellation without requiring a separate differential pair for the nulling function. The approach allows for efficient use of the bias currents, as the nulling currents (I_{NP}) can share the same bias structure as the main input pair.

The output voltage (V_{OUT}) is taken from the shared node between the drain terminals of the sixth n-channel transistor (Q_{P6}) 316 and the fifth n-channel transistor (Q_{N5}) 322. The shared node represents the high-impedance output of the folded cascode structure. The voltage at this node is influenced by the differential input signals (V_{IN}_{⁺} and V_{IN}_{^{−}}) as well as the nulling signals (V_{NP}_{⁺} and V_{NP}_{^{−}}).

The main differential pair processes the input signals V_{IN}_{^{−}} and V_{IN}_{⁺}. The resulting current differences are then “folded” up through the third p-channel transistor (Q_{P3}) 306 and the fourth p-channel transistor (Q_{P4}) 308. The cascode transistors increase the output impedance and voltage gain.

Simultaneously, the first p-channel transistor (Q_{P1}) 302 and the second p-channel transistor (Q_{P2}) 304 inject nulling currents (I_{NP}) that can offset any imbalance in the main differential pair of transistors, effectively canceling input-referred offset voltages.

The nulling currents (I_{NP}) are selected to achieve the desired nulling port gain. The selection is typically made under the constraint that

$$\frac{{I}_{TAIL}}{2} + {I}_{B 2} = {I}_{B 1} + {I}_{NP} .$$

The relationship ensures that adding the nulling function does not increase the overall current consumption of the main amplifier 202.

The combined effect of the main input signals and the nulling signals determines the current flowing through sixth n-channel transistor (Q_{P6}) 316 and the fifth n-channel transistor (Q_{N5}) 322, which sets the output voltage (V_{OUT}). By adjusting the nulling signals (V_{NP}_{⁺} and V_{NP}_{^{−}}), the nulling port circuit 300 can compensate for offset voltages, resulting in a more accurate output voltage that better represents the true differential input.

Nulling port circuit 300 may offer advantages in terms of power efficiency compared to traditional nulling port implementations. By avoiding a separate differential pair for nulling, the nulling port circuit 300 can achieve offset cancellation with minimal additional current consumption beyond what is required for the main amplifier function. The folded cascode configuration provides high gain and good common-mode rejection, while the integrated nulling inputs allow continuous offset correction. By adjusting the relative strengths of the nulling currents (I_{NP}) and the tail current (I_{TAIL}), the nulling port circuit 300 can balance the contributions of the main and nulling inputs, optimizing offset cancellation and overall amplifier performance.

The nulling port circuit 300 offers several advantages over previous implementations of nulling techniques in operational amplifiers. One benefit is the efficient use of transistors. The nulling port circuit 300 utilizes the same number of transistors as a typical folded cascode stage, avoiding the need for additional components that would increase the overall chip area. This approach contrasts with previous solutions, which often require at least one additional differential pair to implement the nulling function, increasing area usage.

Another advantage lies in the current efficiency of the nulling port circuit 300. If the nulling currents (I_{NP}) are lower than half the tail current

$$( {I}_{TAIL} ) ( i . e . , \frac{{I}_{TAIL}}{2} > {I}_{NP} ) ,$$

no additional current is required beyond what is already used in the main amplifier stage. This characteristic allows for the implementation of the nulling function without increasing the overall current consumption of the main amplifier 202.

The current efficiency of the nulling port circuit 300 starkly contrasts previous solutions, where the current in the nulling port differential pair is added to the total current consumption of the main amplifier 202. In such designs, implementing the nulling function invariably leads to an increase in power consumption. However, the approach used in nulling port circuit 300 allows for offset cancellation and nulling functionality to be achieved while potentially maintaining the same current consumption as a standard folded cascode amplifier without nulling capabilities.

FIG. 4 illustrates a schematic of an embodiment nulling circuit 400 in a single-ended topology. Like the fully differential topology in FIG. 2, the nulling circuit 400 includes a nulling amplifier 404, a main amplifier 402, and a resistor divider 206. However, in this single-ended configuration, the nulling amplifier 404 has only one output coupling to the nulling port 408 of the main amplifier 402. The main amplifier 402 may be implemented as the power amplifier (PA) 106, the trans-impedance amplifier (TIA) 122, or both.

The single-ended topology maintains the same basic principle of offset cancellation and flicker noise reduction as the fully differential topology of the nulling circuit 200. The difference lies in the number of nulling signals and their application to the main amplifier 402. The configuration is suitable for applications where circuit simplicity or reduced power consumption is prioritized over the advantages of fully differential signaling.

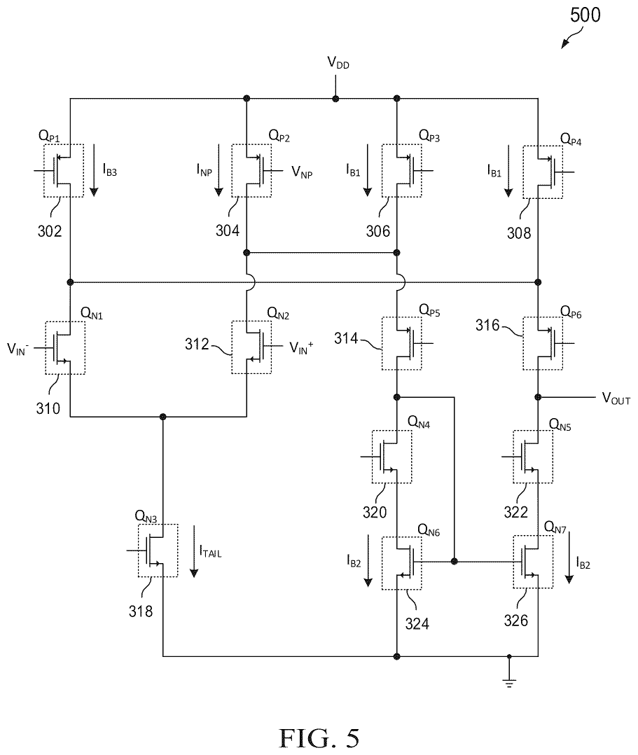

FIG. 5 illustrates a schematic of an embodiment nulling port circuit 500 for a single-ended topology, which may be implemented as the nulling port 408 in the circuit of FIG. 4. The nulling port circuit 500 shares many similarities with the fully differential version shown in FIG. 3, including the folded cascode structure and the integration of the nulling function into the input stage of the main amplifier 402.

The primary difference in the nulling port circuit 500 is the presence of one nulling input (V_{NP}) instead of the differential nulling inputs (V_{NP}_{⁺} and V_{NP}_{^{−}}) in the fully differential version. The single nulling input is typically applied to one side of the input differential pair, allowing for offset cancellation with a simpler circuit topology.

In embodiments, the first p-channel transistor (Q_{P3}) 302 for the nulling port circuit 500 may be implemented as individual current generators.

The single-ended and fully differential topologies provide offset cancellation and reduce flicker noise without significantly increasing the amplifier's overall current consumption. The choice between the topologies depends on the application's specific requirements, such as noise immunity, power consumption, and circuit complexity.

It is noted that all steps outlined in the flow charts of the method are not necessarily required and can be optional. Further, changes to the arrangement of the steps, removal of one or more steps and path connections, and addition of steps and path connections are similarly contemplated.

A first aspect relates to an analog front-end (AFE) circuit. The AFE circuit comprising a power amplifier; and a trans-impedance amplifier, wherein at least one of the power amplifier or trans-impedance amplifier comprises a differential pair of transistors receiving input signals, a folded cascode structure coupled to the differential pair of transistors, and a nulling transistor coupled to the differential pair of transistors, the nulling transistor receiving a nulling signal, and wherein a tail current of the differential pair of transistors, bias currents in the folded cascode structure, and a nulling current through the nulling transistor are selected such that a sum of half the tail current and a first bias current equals a sum of a second bias current and the nulling current, thereby reducing flicker noise and offset of the power amplifier or the trans-impedance amplifier.

In a first implementation form of the AFE circuit, according to the first aspect as such, the nulling transistor comprises a pair of p-channel transistors having source terminals coupled to a supply voltage and drain terminals coupled to drain terminals of the differential pair of transistors.

In a second implementation form of the AFE circuit, according to the first aspect as such or any preceding implementation form of the first aspect, the AFE circuit further comprising a nulling amplifier providing the nulling signal to the nulling transistor.

In a third implementation form of the AFE circuit, according to the first aspect as such or any preceding implementation form of the first aspect, the AFE circuit further comprising a resistor divider coupled between an output of the power amplifier or the trans-impedance amplifier and an input of the nulling amplifier.

In a fourth implementation form of the AFE circuit, according to the first aspect as such or any preceding implementation form of the first aspect, the folded cascode structure comprises a first pair of p-channel transistors serving as current sources; a second pair of p-channel transistors; a pair of n-channel transistors that form a cascode arrangement with the second pair of p-channel transistors; and a pair of n-channel transistors serving as additional current sources.

In a fifth implementation form of the AFE circuit, according to the first aspect as such or any preceding implementation form of the first aspect, the power amplifier or the trans-impedance amplifier is configured in a fully differential topology or a single-ended topology.

In a sixth implementation form of the AFE circuit, according to the first aspect as such or any preceding implementation form of the first aspect, the first bias current flows through a pair of transistors serving as current sources in the folded cascode structure, and the second bias current flows through another pair of transistors in the folded cascode structure.

A second aspect relates to an operational amplifier comprising a main differential pair of n-channel transistors receiving input signals; a folded cascode structure coupled to the differential pair of transistors; and a pair of p-channel nulling transistors, each having a source terminal coupled to a supply voltage and a drain terminal coupled to a drain terminal of a respective transistor of the differential pair of transistors, wherein the pair of p-channel nulling transistors receive nulling signals, and wherein a tail current of the differential pair of transistors, bias currents in the folded cascode structure, and nulling currents through the pair of p-channel nulling transistors are selected such that a sum of half the tail current and a first bias current equals a sum of a second bias current and the nulling currents, thereby reducing flicker noise and offset of the operational amplifier.

In a first implementation form of the operational amplifier, according to the second aspect as such, the folded cascode structure comprises a first pair of p-channel transistors serving as current sources; a second pair of p-channel transistors and a first pair of n-channel transistors forming a cascode arrangement; and a second pair of n-channel transistors serving as additional current sources.

In a second implementation form of the operational amplifier, according to the second aspect as such or any preceding implementation form of the second aspect, the operational amplifier is configured in a fully differential or a single-ended topology with a p-channel nulling transistor receiving a nulling signal and the other p-channel nulling transistor configured as a current source.

In a third implementation form of the operational amplifier, according to the second aspect as such or any preceding implementation form of the second aspect, the first bias current flows through a pair of transistors serving as current sources in the folded cascode structure, and the second bias current flows through another pair of transistors in the folded cascode structure.

In a fourth implementation form of the operational amplifier, according to the second aspect as such or any preceding implementation form of the second aspect, the nulling signals are provided by a nulling amplifier.

In a fifth implementation form of the operational amplifier, according to the second aspect as such or any preceding implementation form of the second aspect, the operational amplifier further comprising a resistor divider coupled between an output of the operational amplifier and an input of the nulling amplifier.

In a sixth implementation form of the operational amplifier, according to the second aspect as such or any preceding implementation form of the second aspect, a common mode of the nulling signals is controlled to maintain a specific gate-to-source voltage of the pair of p-channel nulling transistors.

A third aspect relates to a nulling circuit. The nulling circuit comprising a main amplifier including a differential pair of transistors receiving input signals, a folded cascode structure coupled to the differential pair of transistors, and at least one nulling transistor coupled to the differential pair of transistors; a nulling amplifier providing a nulling signal to the at least one nulling transistor; and a resistor divider coupled between an output of the main amplifier and an input of the nulling amplifier, wherein a tail current of the differential pair of transistors, bias currents in the folded cascode structure, and a nulling current through the at least one nulling transistor are selected such that a sum of half the tail current and a first bias current equals a sum of a second bias current and the nulling current, thereby reducing flicker noise and offset of the main amplifier.

In a first implementation form of the nulling circuit, according to the third aspect as such, the at least one nulling transistor comprises a pair of p-channel transistors having source terminals coupled to a supply voltage and drain terminals coupled to drain terminals of the differential pair of transistors.

In a second implementation form of the nulling circuit, according to the third aspect as such or any preceding implementation form of the third aspect, the folded cascode structure comprises a first pair of p-channel transistors serving as current sources; a second pair of p-channel transistors and a first pair of n-channel transistors forming a cascode arrangement; and a second pair of n-channel transistors serving as additional current sources.

In a third implementation form of the nulling circuit, according to the third aspect as such or any preceding implementation form of the third aspect, the first bias current flows through a pair of transistors serving as current sources in the folded cascode structure, and the second bias current flows through another pair of transistors in the folded cascode structure.

In a fourth implementation form of the nulling circuit, according to the third aspect as such or any preceding implementation form of the third aspect, the main amplifier is configured in a fully differential topology or a single-ended topology.

In a fifth implementation form of the nulling circuit, according to the third aspect as such or any preceding implementation form of the third aspect, a common mode of the nulling signal is controlled to maintain a specific gate-to-source voltage of the at least one nulling transistor.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. An analog front-end (AFE) circuit, comprising:
a power amplifier; and
a trans-impedance amplifier,
wherein at least one of the power amplifier or trans-impedance amplifier comprises:
a differential pair of transistors receiving input signals,
a folded cascode structure coupled to the differential pair of transistors, and
a nulling transistor coupled to the differential pair of transistors, the nulling transistor receiving a nulling signal, and
wherein a tail current of the differential pair of transistors, bias currents in the folded cascode structure, and a nulling current through the nulling transistor are selected such that a sum of half the tail current and a first bias current equals a sum of a second bias current and the nulling current, thereby reducing flicker noise and offset of the power amplifier or the trans-impedance amplifier.

2. The AFE circuit of claim 1, wherein the nulling transistor comprises a pair of p-channel transistors having source terminals coupled to a supply voltage and drain terminals coupled to drain terminals of the differential pair of transistors.

3. The AFE circuit of claim 1, further comprising a nulling amplifier providing the nulling signal to the nulling transistor.

4. The AFE circuit of claim 3, further comprising a resistor divider coupled between an output of the power amplifier or the trans-impedance amplifier and an input of the nulling amplifier.

5. The AFE circuit of claim 1, wherein the folded cascode structure comprises:
a first pair of p-channel transistors serving as current sources;
a second pair of p-channel transistors;
a pair of n-channel transistors that form a cascode arrangement with the second pair of p-channel transistors; and
a pair of n-channel transistors serving as additional current sources.

6. The AFE circuit of claim 1, wherein the power amplifier or the trans-impedance amplifier is configured in a fully differential topology or a single-ended topology.

7. The AFE circuit of claim 1, wherein the first bias current flows through a pair of transistors serving as current sources in the folded cascode structure, and the second bias current flows through another pair of transistors in the folded cascode structure.

8. An operational amplifier, comprising:
a main differential pair of n-channel transistors receiving input signals;
a folded cascode structure coupled to the differential pair of transistors; and
a pair of p-channel nulling transistors, each having a source terminal coupled to a supply voltage and a drain terminal coupled to a drain terminal of a respective transistor of the differential pair of transistors,
wherein the pair of p-channel nulling transistors receive nulling signals, and
wherein a tail current of the differential pair of transistors, bias currents in the folded cascode structure, and nulling currents through the pair of p-channel nulling transistors are selected such that a sum of half the tail current and a first bias current equals a sum of a second bias current and the nulling currents, thereby reducing flicker noise and offset of the operational amplifier.

9. The operational amplifier of claim 8, wherein the folded cascode structure comprises:
a first pair of p-channel transistors serving as current sources;
a second pair of p-channel transistors and a first pair of n-channel transistors forming a cascode arrangement; and
a second pair of n-channel transistors serving as additional current sources.

10. The operational amplifier of claim 8, wherein the operational amplifier is configured in a fully differential or a single-ended topology with a p-channel nulling transistor receiving a nulling signal and the other p-channel nulling transistor configured as a current source.

11. The operational amplifier of claim 8, wherein the first bias current flows through a pair of transistors serving as current sources in the folded cascode structure, and the second bias current flows through another pair of transistors in the folded cascode structure.

12. The operational amplifier of claim 8, wherein the nulling signals are provided by a nulling amplifier.

13. The operational amplifier of claim 12, further comprising a resistor divider coupled between an output of the operational amplifier and an input of the nulling amplifier.

14. The operational amplifier of claim 8, wherein a common mode of the nulling signals is controlled to maintain a specific gate-to-source voltage of the pair of p-channel nulling transistors.

15. A nulling circuit, comprising:
a main amplifier including:
a differential pair of transistors receiving input signals,
a folded cascode structure coupled to the differential pair of transistors, and
at least one nulling transistor coupled to the differential pair of transistors;
a nulling amplifier providing a nulling signal to the at least one nulling transistor; and
a resistor divider coupled between an output of the main amplifier and an input of the nulling amplifier,
wherein a tail current of the differential pair of transistors, bias currents in the folded cascode structure, and a nulling current through the at least one nulling transistor are selected such that a sum of half the tail current and a first bias current equals a sum of a second bias current and the nulling current, thereby reducing flicker noise and offset of the main amplifier.

16. The nulling circuit of claim 15, wherein the at least one nulling transistor comprises a pair of p-channel transistors having source terminals coupled to a supply voltage and drain terminals coupled to drain terminals of the differential pair of transistors.

17. The nulling circuit of claim 15, wherein the folded cascode structure comprises:
a first pair of p-channel transistors serving as current sources;
a second pair of p-channel transistors and a first pair of n-channel transistors forming a cascode arrangement; and
a second pair of n-channel transistors serving as additional current sources.

18. The nulling circuit of claim 15, wherein the first bias current flows through a pair of transistors serving as current sources in the folded cascode structure, and the second bias current flows through another pair of transistors in the folded cascode structure.

19. The nulling circuit of claim 15, wherein the main amplifier is configured in a fully differential topology or a single-ended topology.

20. The nulling circuit of claim 15, wherein a common mode of the nulling signal is controlled to maintain a specific gate-to-source voltage of the at least one nulling transistor.
